(19) United States
(12) Patent Application Publication
(10) Pub. No.: US 2018/0230595 A1
(43) Pub. Date: Aug. 16, 2018

(54) VAPOR PHASE FILM-FORMING APPARATUS

(71) Applicant: HERMES-EPITEK CORPORATION, Taipei City (TW)

(72) Inventors: Noboru Suda, Tokyo-to (JP); Takahiro Oishi, Tokyo-to (JP); Junji Komeno, Tokyo-to (JP); Po-Jung Lin, Hsinchu (TW)

(21) Appl. No.: 15/892,426

(22) Filed: Feb. 9, 2018

(30) Foreign Application Priority Data
Feb. 16, 2017 (JP) 2017-026627

(51) Int. Cl. C23C 16/44; C23C 16/52; C23C 16/455; C23C 16/46

(52) U.S. Cl. CPC C23C 16/4408; C23C 16/52; C23C 16/46; C23C 16/45568; C23C 16/45519

(57) ABSTRACT

In an embodiment, a vapor phase film-forming apparatus 10 includes a susceptor 12 for holding a film forming substrate 14. A flow channel 40 is formed horizontally by the opposite surface 20 facing the susceptor 12. In the flow channel 40, a material gas introduction port 42 and material gas and a purge gas exhaust port 48 are provided. On the opposite surface 20, many purge gas nozzles 36 are provided and divided into a plurality of purge areas PE1-PE 3. Mass flow controllers (MFCs) 52A-52C and 62A-62C for adjusting the flow rate for each purge area are provided in each purge area. Then, the mass flow rate of the purge gas is controlled by the MFCs 52A-52C and 62A-62C for each purge area.

### CROSS-REFERENCE TO RELATED APPLICATIONS

The entire contents of Japan Patent Application No. 2017-026627, filed on Feb. 16, 2017, from which this application claims priority, are expressly incorporated herein by reference.

### BACKGROUND OF THE INVENTION

### 1. Field of the Invention

The present invention relates to a vapor phase film-forming apparatus for depositing semiconductor films on a semiconductor or an oxide substrate, and more particularly, relates to an apparatus for suppression (or reduction) of deposits.

### 2. Description of Related Art

A vapor phase film-forming apparatus for forming a film by vapor phase generally includes a horizontal reaction furnace or a planetary motion reaction furnace. In either case, the reacting material gases are carried into the furnace and then flow in the horizontal direction to form a film on a substrate. However, deposits have accumulated on gas channels and an opposite surface opposite to the substrate. As a result, the raw material efficiency is lowered and the maintenance frequency of the opposite surface becomes high, leading to an increase in cost.

From the viewpoint of suppressing or reducing deposits on the opposite surface, the following patent documents disclose varied techniques. For example, patent document 1 adopts a method of pressurized gas (hereinafter referred to as “opposite surface purge gas” or simply “purge gas “or” opposite surface purge”). The object of this method is not to suppress the deposits. However, this method has drawback that the purge flow are unstable, and there is a high possibility to generate turbulence and vortex, so that a uniform down flow cannot be formed and therefore is difficult to reduce deposits.

In addition, patent document 2 proposed a showerhead-shaped opposite surface. However, since the opposite surface is not directly water-cooled, the temperature is high. The decomposition and diffusion of the material gases are unstable, resulting in serious deposits even when purge gas has been introduced. Patent document 3 describes a technique in which the concept of the opposite surface purge is applied to the planetary motion reaction furnace. However, in this technique, since the opposite surface is not directly water-cooled, it is conceivable that the accumulated deposits are severe.

Therefore, it can be considered to provide a shower head as a means for cooling the opposite surface and to introduce a purge gas. Patent document 4 discloses a technique relates to such means. Patent document 4 discloses a technique in which a water-cooled shower head is provided although it is for raw material gases. In addition, patent document 5 discloses a technique of using a water-cooled shower head or a slit array of nozzle structure, in which the outlet of the shower head or nozzle is taper-shaped. Furthermore, patent documents 6-7 disclose a structure, in which the opposite surface purge is divided into a plurality of zones (or areas), and a hole density is different in each zone for enhancing the purging effect.

### CITED PATENT DOCUMENTS

Patent document 1: Japanese Unexamined Patent Application Publication No. 4-164895 (referring to FIGS. 1 and 2)

Patent document 2: Japanese Unexamined Patent Application Publication No. 2001-250783 (referring to FIG. 1)

Patent document 3: Japanese Unexamined Patent Application Publication No. 2010-232624 (referring to FIG. 4)

Patent document 4: Japanese Unexamined Patent Application Publication No. 8-91989

Patent document 5: U.S. Patent Application Publication No. 2011/091648

Patent document 6: Japanese Unexamined Patent Application Publication No. 2002-110564

Patent document 7: Japanese Unexamined Patent Application Publication No. 2002-2992440

However, the techniques described in the above patent documents have the following problems. First, in the cooling method as described in patent document 4 and patent document 5, even if the surface has been cooled, a part of the vapor phase decomposed materials in the high temperature region will be diffused to the opposite surface. Then, when the decomposed materials reach over the opposite surface, at least a part of it will inevitably be deposited on the opposite surface.

In addition, patent documents 1-3 disclose technique of suppressing diffusion to the opposite surface by using the purge gas. If the flow momentum of the purge gas is weak, a considerable amount of the vapor-phase material molecules diffuse to the opposite surface. Needless to say, if a large amount of purge gas flows, it can prevent most of the vapor-phase material molecules diffuse to the opposite surface. However, the area of the opposite surface is very large, when purging the entire opposite surface with considerable momentum, an enormous amount of purge gas is required. When the amount of purge gas increases, both the cost of purge gas and the load of exhaust pump or exhaust gas treatment equipment increase, thereby increasing the cost of equipment and peripheral equipment.

Furthermore, patent documents 6 and 7 provide a method, which alters the purge ratio by zonally dividing the purge gas and changing the density of holes in the angular zone. The method had the following problems. In producing a compound semiconductor device, generally different types of films (for example, GaAs layer and InGaP layer) are formed during a batch procedure. Therefore, when the film type is changed, the deposition state on the opposite surface will also be changed. Accordingly, the flow rate in each purge zone must be changeable in the same batch procedure. However, patent document 6 and patent document 7 disclose a structure in which the purge intensity is changed by the density of holes. The purge ratio is set suitable for only one compound semiconductor film. There is a disadvantage that the purge ratio cannot be controlled when different types of compound films are formed in a same batch procedure.

### SUMMARY OF THE INVENTION

The present invention focuses on the above-mentioned problems, and an object of the present invention is to provide a vapor phase film-forming apparatus capable of suppressing or reducing deposits on the opposite surface.

The present invention relates to a film-forming apparatus comprising: a susceptor for holding a film-forming substrate; an opposite surface facing the susceptor and the film-forming substrate and forming a flow channel in the horizontal direction; an introduce portion for introducing a material gas into the flow channel; an exhaust unit for exhausting the gas having passed through the flow channel; and a plurality of purge gas nozzles provided in the opposite surface for uniformly supplying a purge gas toward the susceptor, wherein the opposite surface is divided into a plurality of purge areas with each including a plurality of purge gas nozzles, and a plurality of mass flow controllers for controlling the flow rate of purge gas are provided for each of the plurality of purge areas.

In one major embodiment, when the side that the material gas being introduced is set as the upstream and the side that the gas being exhausted is set as the downstream, the opposite surface is divided into a plurality of purge areas in the upstream/downstream direction. In another embodiment, the plurality of mass flow controllers are configured to adjust the flow rate so that a larger amount of purge gas flow the purge areas with severe deposits on the opposite surface. In still another embodiment, the purge gas nozzle is a shower head type or slit type nozzle array.

In still another embodiment, the outlet of the purge gas nozzle is reversely-tapered. In still another embodiment, the purge gas is hydrogen or nitrogen, or a mixed gas thereof. And cooling means for cooling the opposite surface is also provided. The foregoing and other objects, features, and advantages of the present invention will become apparent from the following detailed description and the accompanying drawings.

According to the present invention, there is provided a vapor phase film-forming apparatus including a susceptor for holding a film-forming substrate, an opposite surface facing the susceptor and the film-forming substrate and forming a flow channel in the horizontal direction, an introduction portion for introducing a material gas into the flow channel, an exhaust unit for exhausting the gas having passed through the flow channel, and a plurality of purge gas nozzles provided in the opposite surface for uniformly supplying a purge gas toward the susceptor, wherein the opposite surface is divided into a plurality of purge areas with each including a plurality of purge gas nozzles, and a plurality of mass flow controllers for controlling the flow rate of purge gas are provided for each of the plurality of purge areas. Therefore, it is possible to suppress (reduce) deposits on the opposite surface, thereby improving the raw material efficiency and the maintenance frequency of the opposite surface.

### BRIEF DESCRIPTION OF THE DRAWINGS

FIG. 1 is a cross-sectional view showing major components of a horizontal furnace type of vapor phase film-forming apparatus according to a first embodiment of the present invention.

FIG. 2A is a plan view of a vapor phase film-forming apparatus of the first embodiment, and FIG. 2B is a diagram explaining the uniform down flow of the first embodiment.

FIG. 3A is a diagram showing a configuration of a reactor model (horizontal furnace type) of a two-dimensional simulation of the present invention, and FIG. 3B is an explanatory view of wall adjacent cells of the two-dimensional simulation.

FIG. 4 is an example of a flow pattern under condition 1 in the two-dimensional simulation.

FIG. 5 is an example of a flow pattern under condition 5 in the two-dimensional simulation.

FIG. 6 is an example of a flow pattern under condition 10 in the two-dimensional simulation.

FIG. 7 is an example of a concentration distribution under condition 1 in the two-dimensional simulation.

FIG. 8 is an example of a concentration distribution under condition 5 in the two-dimensional simulation.

FIG. 9 is an example of a concentration distribution under condition 10 in the two-dimensional simulation.

FIG. 10 is a graph showing a deposition rate distribution on wall surface of the substrate side in the two-dimensional simulation (when the purge amount is uniformly varied from the whole).

FIG. 11 is a graph showing a deposition rate distribution on opposite surface in the two-dimensional simulation (when the purge amount is uniformly varied from the whole).

FIG. 12 is a graph showing relationships between the flow rate of purge gas and the deposition amounts on the wall surface of the substrate side or the deposition amounts on the opposite surface (when the purge amount is uniformly varied from the whole).

FIG. 13 is a graph showing a deposition rate distribution (purge introduction position dependency) on wall surface of the substrate side in the two-dimensional simulation.

FIG. 14 is a graph showing a deposition rate distribution (purge introduction position dependency) on an opposite surface in the two-dimensional simulation.

FIG. 15 is a graph showing a deposition rate distribution on wall surface of the substrate side in the two-dimensional simulation (in a case where the purge amount is changed by supplying the purge gas only from the upstream region).

FIG. 16 is a graph showing a deposition rate distribution on the opposite surface in the two-dimensional simulation (in a case where the purge amount is changed by supplying the purge gas only from the upstream region).

FIG. 17 is a graph showing a comparison between a case where the purge in the two-dimensional simulation is performed from the whole and a case in which the purge is flowed from the upstream region.

FIG. 18 is a graph showing the deposition rate distribution on the wall surface of the substrate side in the two-dimensional simulation (when the purge ratios at the introduction positions are changed while the total purge amount is fixed).

FIG. 19 is a graph showing the deposition rate distribution on the opposite surface in the two-dimensional simulation (when the purge ratios are changed at the introduction positions while the total purge amount is fixed).

FIG. 20A is a cross-sectional view showing the entire configuration, and FIG. 20B is a sectional view showing the major part showing the area division (zone division) of a vapor phase film-forming apparatus of a second embodiment of the present invention.

FIG. 21A is a cross-sectional view showing a major part of a vapor phase film-forming apparatus of a third embodiment of the present invention and FIG. 21B is a cross-sectional view showing a comparative example.

FIG. 22A is a view showing a nozzle arrangement of a slit type nozzle of a horizontal type furnace according to another embodiment of the present invention, and FIG. 22B is a view showing a nozzle arrangement of a slit type nozzle of a planetary motion reaction furnace according to another embodiment of the present invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. Wherever possible, the same or similar reference numbers are used in drawings and the description to refer to the same or like parts.

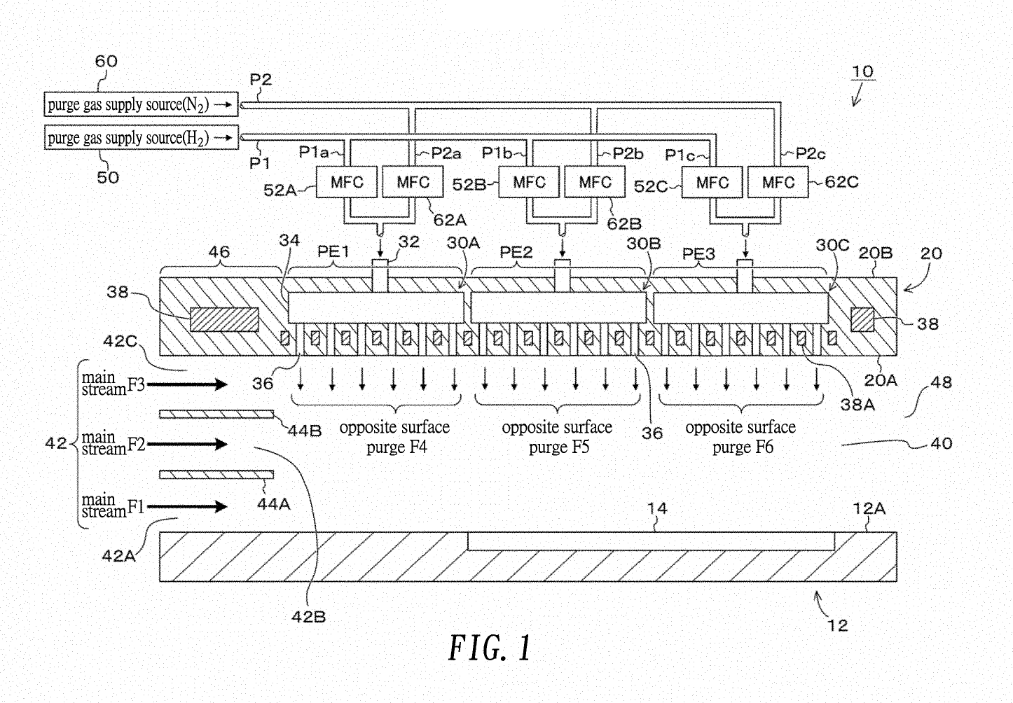

First, embodiment 1 of the present invention will be described with reference to FIGS. 1-19.

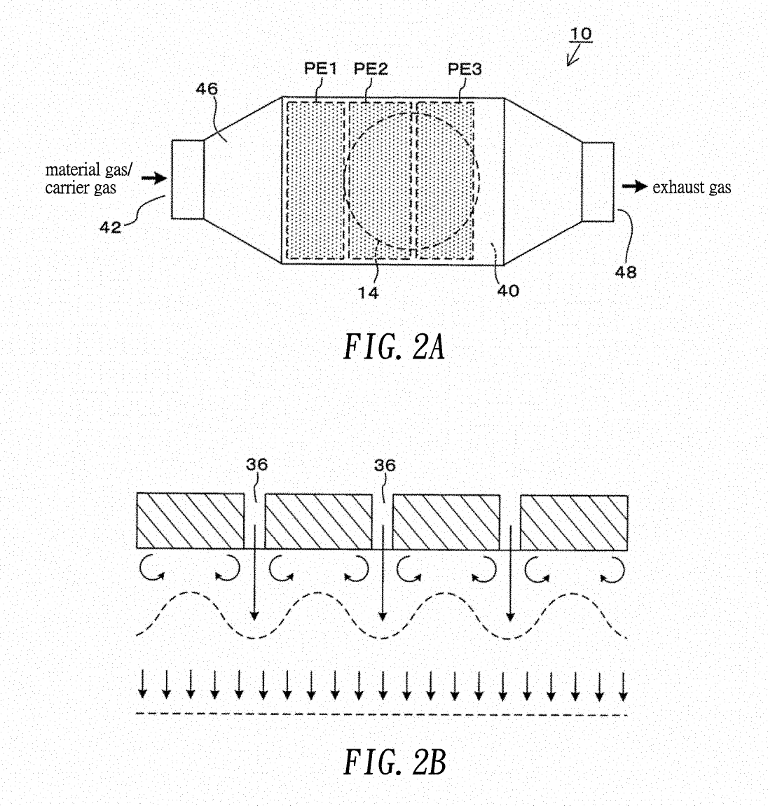

First, FIG. 1, FIG. 2A, and FIG. 2B show the structure of the vapor phase film-forming apparatus of this example. FIG. 1 is a cross-sectional view showing the major structure of the vapor phase film-forming apparatus. FIG. 2A is a plan view showing a purge area division of the vapor phase film-forming apparatus, and FIG. 2B is a cross sectional view showing an example of uniform down flow.

As shown in FIGS. 1, 2A, and 2B, the vapor phase film-forming apparatus 10 of this embodiment is a horizontal type furnace, and has a structure in which an opposite surface 20 is arranged to face a main surface 12A of a susceptor 12 for holding a substrate 14 to deposit a film thereon. In addition, a flow channel 40 is arranged between the main surface 12A and a main surface 20A of the opposite surface 20 for film formation. The flow channel 40 is formed in the horizontal direction, and the material gas (including carrier gas) is introduced from a material gas introduction port 42. In this example, the material gas introduction port 42 is divided into three gas introduction ports 42A/42B/42C by two partition plates 44 A and 44 B parallel to the main surface 12 A of the susceptor 12 and the main surface 20A of the opposite surface 20. Further, the flow channel 40 is provided with an exhaust port 48 for exhausting the material gas introduced from the gas introduction port 42 and the purge gas introduced from a purge gas nozzle 36, which will be described later.

As shown in FIGS. 1, 2A, and 2B, a plurality of purge gas nozzles 36 for supplying a purge gas (pressurized gas) are provided on the opposite surface 20. The purge gas nozzle 36 supplies a purge gas (pressurized gas) toward the susceptor 12 (and the substrate 14). In this embodiment, since the reaction furnace is a face-up type, the purge gas nozzle 36 forms a uniform down flow on the opposite surface 20. A uniform down flow means that the downstream in FIG. 2B has a uniform downward flow velocity at a position slightly away from the outlet hole of the purge gas nozzle 36. For the sake of easy understanding, in the drawings other than FIG. 2B, a portion where the flow velocity in the vicinity of the outlet hole of the purge gas nozzle 36 is not uniform has been omitted, and a portion having a uniform flow velocity is denoted by a downward arrow (in the case of downstream). Further, the opposite surface 20 is divided into a plurality of purge areas (or purge zones), PE1-PE3, and each purge area PE1-PE3 includes a plurality of purge gas nozzles 36.

In this embodiment, as shown in FIG. 1, a shower head type of purge gas nozzle is used. Specifically, shower heads 30A-30C corresponding to the respective purge areas PE1-PE3 are provided in the opposite surface 20. The shower head 30A is provided with a hollow head portion 34 in the opposite surface 20, an introduction portion 32 for supplying a purge gas to the head portion 34, and a plurality of purge gas nozzles 36 communicating with the head portion 34. The terminal of the purge gas nozzle 36 is toward the flow channel 40. The other shower heads 30B and 30C have the same configuration as the shower head 30A.

In this embodiment, the opposite surface 20 is provided with a cooling device 38 for cooling the opposite surface 20. A plurality of cooling pipes 38A connected to the cooling device 38 are disposed between the purge gas nozzles 36. The opposite surface 20 is cooled by the cooling medium within the cooling pipes 38A. As shown in FIG. 2A, in addition, the opposite surface 20 is divided into a plurality of purge areas PE1-PE3 in the upstream/downstream direction when the material gas introduction port 42 of the material gas is referred to as the upstream side and the exhaust port 48 side is referred to as the downstream side.

In addition, purge gases are supplied from the purge gas supply sources 50/60 to the shower heads 30A-30C. In the present embodiment, hydrogen gas (H₂) and nitrogen gas (N₂) are used as the purge gas. H₂ is supplied from the purge gas supply source 50, and N₂ is supplied from the other purge gas supply source 60. A mass flow controller (hereinafter referred to as “MFC”) for adjusting the flow rate of the purge gas for each purge area is provided between the supply sources 50/60 and the shower heads 30A-30C. Specifically, a pipe P1 connects with the purge gas supply source 50 (H₂), and the pipe P1 is branched to three pipes P1a, P1b, and P1c for connecting to MFCs 52A, 52B, and 52C, respectively. A pipe P2 connects with the purge gas supply source 60 (N₂), and the pipe P2 is branched into three pipes P2a, P2b, P2c for connecting to MFCs 62A, 62B, 62C, respectively. The flow rate of purge gases are controlled by these MFCs 52A-52C and 62A-62C and then the purge gases are supplied to the shower heads 30A-30C via pipes 32A-32C.

That is, each purge area PE1-PE3 is provided with one shower heads 30A-30C, and the purge gas is adjusted to be the optimum purge gas flow rate according to type of the purge gas and type of the material gas. The adjusted purge gas is then introduced to the flow channel 40. The purge gas to be introduced may be H₂ or N₂, or a mixed gas thereof. But it does not preclude the use of other known purge gases. The MFCs 52A-52C and 62A-62C adjust the flow rate so that a larger amount of purge gas flows to the portion (zone) where deposition is severe on the opposite surface 20.

An example regarding device type, substrate, gas, film, etc. is described as follows. The vapor phase film-forming apparatus 10 is a horizontal furnace, and a single substrate of 6 inch sapphire is used as a substrate for depositing films thereon. One film to be deposited is gallium nitride, and the gas conditions are F1 (the main stream 1 in the material gas introduction port 42A shown in FIG. 1) (H₂) 2.8 SLM+(NH₃) 2 SLM, F₂ (the main stream 2 in the material gas introduction port 42B shown in FIG. 1) (H₂) 4.8 SLM, and F3 (the main stream 3 in the material gas introduction port 42C shown in FIG. 1) (H₂) 3.8 SLM+(NH₃) 1 SLM. In addition, TMGa is used as the material gas with a flow rate 120 μmol/min. The temperature of the substrate 14 is 1050° C., the film-forming rate was 3 μm/hr, and the film-forming time is 1 hour.

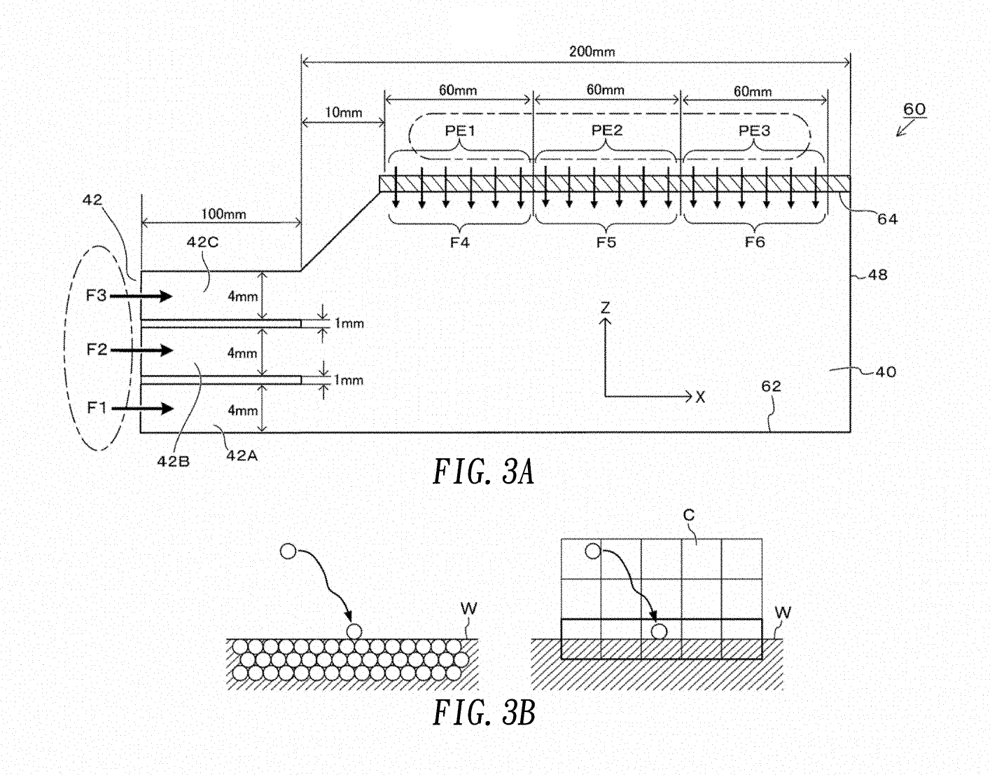

Next, with reference to FIGS. 3-19, the two-dimensional simulation of this embodiment will be described.

(1) Reactor Model: FIG. 3A shows a reactor model (horizontal reaction furnace) of the two-dimensional simulation. The reactor 60 shown in FIG. 3A has the essential structures same as that of the vapor phase film-forming apparatus 10 shown in FIG. 1 and FIG. 2A. The material gas introduction port 42 is divided into three gas introduction ports 42A-42C by two partition plates 44 A and 44B. FIG. 3A shows that the main flow F1 is the process gas introduced from the gas introduction port 42A, the main flow F2 is the process gas introduced from the gas introduction port 42B, and the main flow F3 the process gas introduced from the gas introduction port 42C. Further, the length of the introduction port 42 in the upstream/downstream direction (the left-right direction in FIG. 3A) is set to 100 mm and the height or the thickness (the vertical direction in FIG. 3A) of each introduction port 42A-42C is set to 4 mm.

On the other hand, the side of opposite surface 20 is divided into three purge areas PE1-PE3. The purge gas supplied from the purge area PE1 is referred to as an opposite surface purge F4, the purge gas supplied from the purge area PE2 is referred to as an opposite surface purge F5, and the purge gas supplied from the area PE3 is referred to as an opposite surface purge F6. The length of each of the purge areas PE1-PE3 in the upstream/downstream direction (the left-right direction in FIG. 3A) is 60 mm. The length from the introduction port 42A/B/C to the purge area PE1 is 10 mm, the length from the purge area PE3 to the exhaust port 48 is 10 mm, and the length of the entire flow channel 40 is 200 mm.

(2) Simulation Conditions

The simulation conditions using the reaction furnace 60 are described as follows.

a. The material gas is supplied only from the gas introduction port 42B with a concentration of 1 in arbitrary units.

b. To make a two-dimensional simulation of a horizontal reaction furnace, there is no distribution of conditions in the depth direction.

c. It is assumed that a uniform down flow is established for the opposite surface purge (purge gas).

d. The carrier gas (material gas) and the opposite surface purge gas (purge gas) are hydrogen, and their viscosity coefficients are used.

e. The diffusion coefficient of the most important material TMGa, i.e., a mixture diffusion coefficient of TMGa and its decomposition products in hydrogen, is adopted as the diffusion coefficient of the material gas molecule.

f. For both the susceptor 12 and the opposite surface 20, the deposition mode is assumed to be a mass transport limited mode. That is, two conditions are assumed: (i) once material molecules (which is those include III group element in case of IIIV compound semiconductor) reach to the wall, they will be deposited there immediately, and (ii) so then the material molecule concentration is always kept zero on the wall surface.

(3) Calculation Method

The calculation method of the obtained simulation result under the above conditions is described as follows.

(i) Find the flow pattern with the Navier Stokes equation.

(ii) Solve the advection diffusion equation under the boundary concentration condition shown in above f to obtain the distribution of the material molecule concentration in the flow channel

(iii) After that, the flux (flow rate: the quantity flowing per unit time and per unit area) of the material molecules flowing into the adjacent wall cells is expressed by the formula [D·dC/dz] (D is diffusion coefficient, and dC/dz is vertical concentration gradient). Thus, the deposition rate on the wall surface can be obtained. Here, “wall adjacent cell” is explained in FIG. 3B. Referring to FIG. 3B, as shown on the left side of the figure, in actual physical phenomena, the material molecules always adhere to the wall (W) of susceptor or substrate and do not detach when they reach it. On the other hand, as shown on the right side of FIG. 3B, in the simulation, the space is divided into many cells C and when the material molecule reaches at the interface with the wall W (surrounded by bold lines), it will be taken into the film. At this time, a cell C adjacent to the interface with the wall W is defined as a wall adjacent cell.

(4) Flow Velocity Conditions

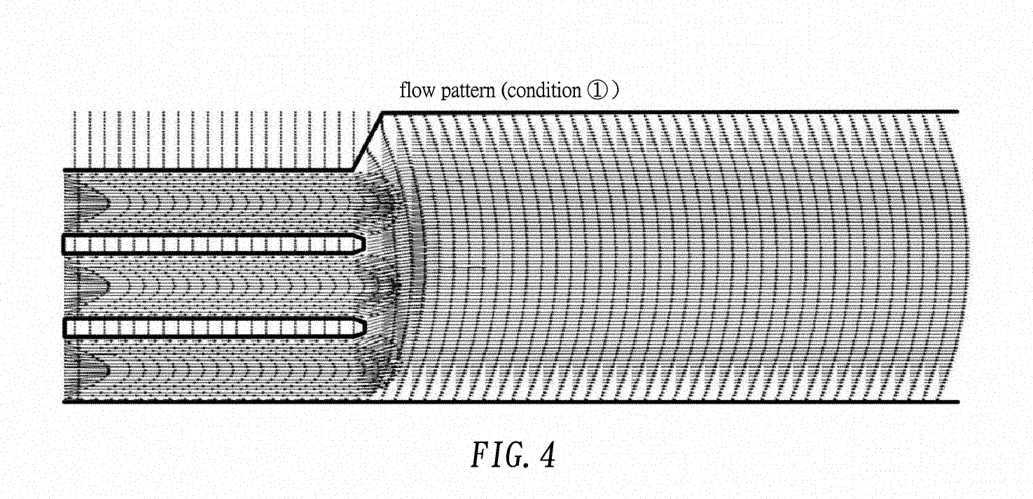

The average flow velocities (unit: m/sec) of the main streams F1-F3 and the opposite surface purges F4-F6 are set to the conditions 1-12 of the following Table 1 (in Tables 1-3 and FIGS. 4-19, numbers of conditions are represented by circled numbers).

TABLE 1

| Conditions | F1 | F2 | F3 | F4 | F5 | F6 |
|---|---|---|---|---|---|---|
| \textcircled{1} | 0.5 | 0.5 | 0.5 | 0 | 0 | 0 |
| \textcircled{2} | 0.5 | 0.5 | 0.5 | 0.0025 | 0.0025 | 0.0025 |
| \textcircled{3} | 0.5 | 0.5 | 0.5 | 0.005 | 0.005 | 0.005 |
| \textcircled{4} | 0.5 | 0.5 | 0.5 | 0.01 | 0.01 | 0.01 |
| \textcircled{5} | 0.5 | 0.5 | 0.5 | 0.02 | 0.02 | 0.02 |
| \textcircled{6} | 0.5 | 0.5 | 0.5 | 0.02 | 0 | 0 |
| \textcircled{7} | 0.5 | 0.5 | 0.5 | 0 | 0.02 | 0 |
| \textcircled{8} | 0.5 | 0.5 | 0.5 | 0 | 0 | 0.02 |
| \textcircled{9} | 0.5 | 0.5 | 0.5 | 0.04 | 0 | 0 |
| \textcircled{10} | 0.5 | 0.5 | 0.5 | 0.06 | 0 | 0 |
| \textcircled{11} | 0.5 | 0.5 | 0.5 | 0.08 | 0 | 0 |
| \textcircled{12} | 0.5 | 0.5 | 0.5 | 0.04 | 0.02 | 0 |

(5) Conversion of Flow Rate

Next, the flow rates (unit: SLM) are converted from the flow velocity conditions of Table 1 and are listed in Table 2. The converting is proceed with conditions that a general growth gas pressure of 20 kPa and a reaction furnace size of 200 mm in depth (i.e., a reaction furnace size of about 6 inches for each furnace) are used. Under the conditions, the flow rate was converted into a flow rate. In the simulation, the flow velocity is stipulated, and in order to convert into flow rate according to the reality, the cross-sectional area of the entrance is required. In the two-dimensional model, although the height has been prescribed, the depth is further required in order to obtain the cross sectional area. Therefore, here, assuming a horizontal reaction furnace for 6 inch one sheet with a depth 200 mm is used. Further, when the flow velocities of the opposite surface purges F4-F6 are set, the total flow rate of the opposite surface purges F4-F6 is set within a range not exceeding the total flow rate of main stream F1-F3. This is because a very large purge flow rate is not realistic.

TABLE 2

| Conditions | F1 | F2 | F3 | F4 | F5 | F6 | Total purge |
|---|---|---|---|---|---|---|---|
| \textcircled{1} | 4.8 | 4.8 | 4.8 | 0 | 0 | 0 | 0 |
| \textcircled{2} | 4.8 | 4.8 | 4.8 | 0.36 | 0.36 | 0.36 | 1.08 |
| \textcircled{3} | 4.8 | 4.8 | 4.8 | 0.72 | 0.72 | 0.72 | 2.16 |
| \textcircled{4} | 4.8 | 4.8 | 4.8 | 1.44 | 1.44 | 1.44 | 4.32 |
| \textcircled{5} | 4.8 | 4.8 | 4.8 | 2.88 | 2.88 | 2.88 | 8.64 |
| \textcircled{6} | 4.8 | 4.8 | 4.8 | 2.88 | 0 | 0 | 2.88 |
| \textcircled{7} | 4.8 | 4.8 | 4.8 | 0 | 2.88 | 0 | 2.88 |
| \textcircled{8} | 4.8 | 4.8 | 4.8 | 0 | 0 | 2.88 | 2.88 |
| \textcircled{9} | 4.8 | 4.8 | 4.8 | 5.76 | 0 | 0 | 5.76 |
| \textcircled{10} | 4.8 | 4.8 | 4.8 | 8.64 | 0 | 0 | 8.64 |
| \textcircled{11} | 4.8 | 4.8 | 4.8 | 11.52 | 0 | 0 | 11.52 |
| \textcircled{12} | 4.8 | 4.8 | 4.8 | 5.76 | 2.88 | 0 | 8.64 |

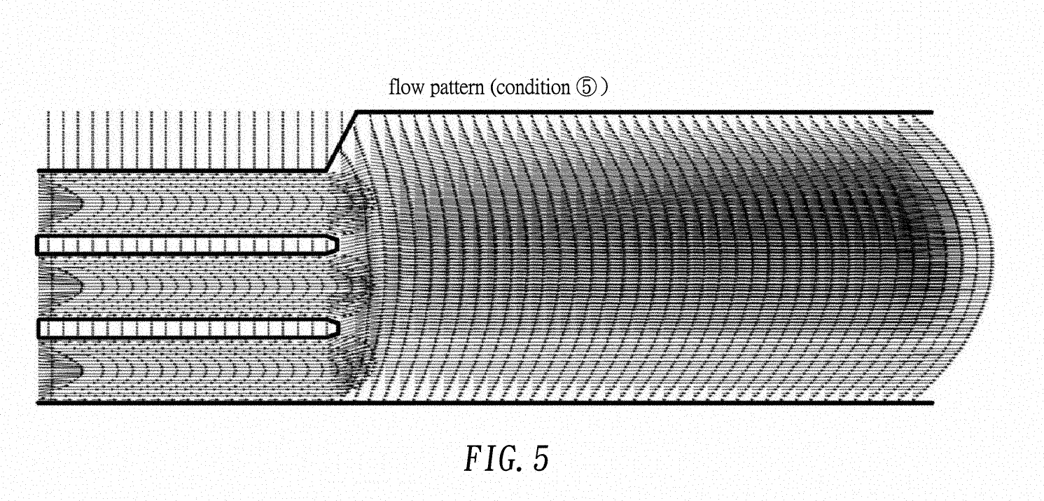

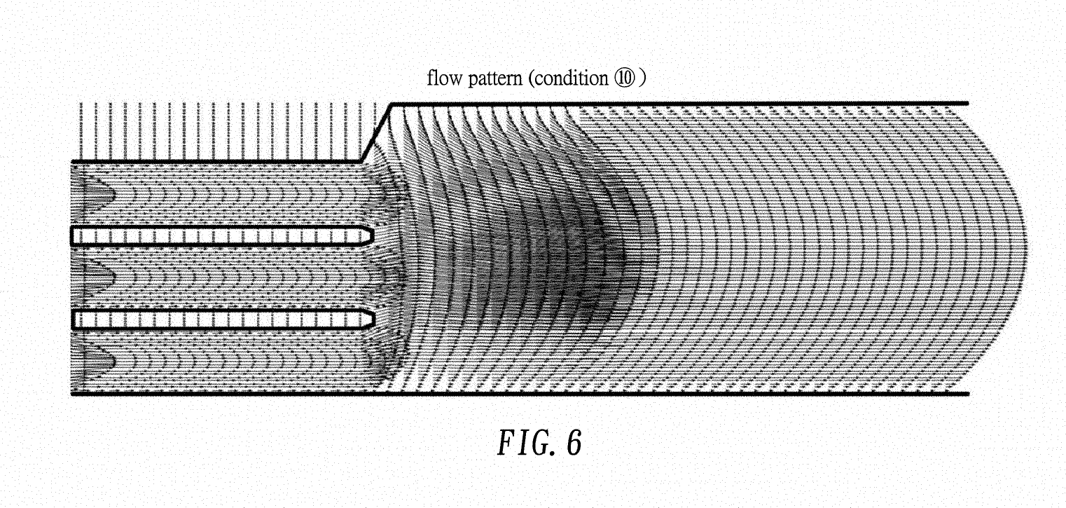

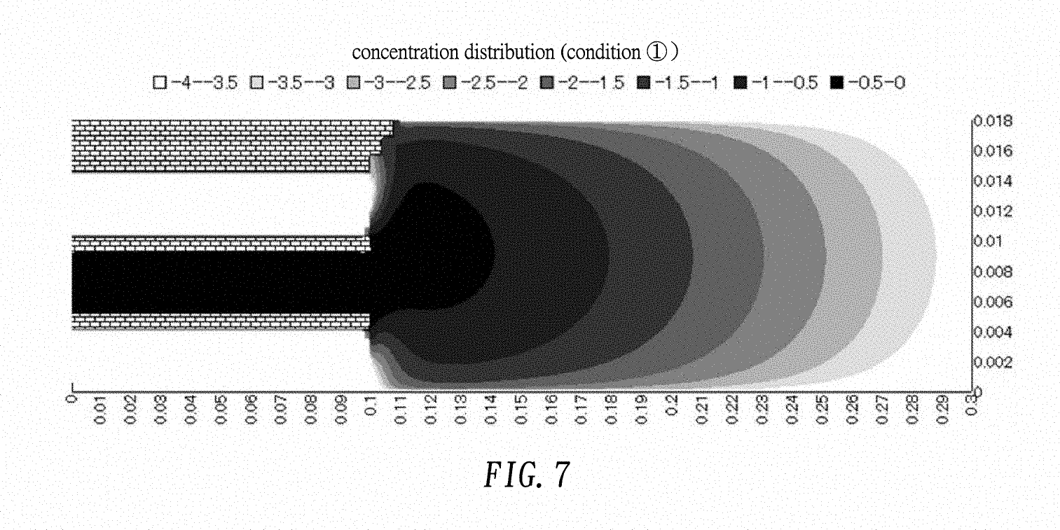

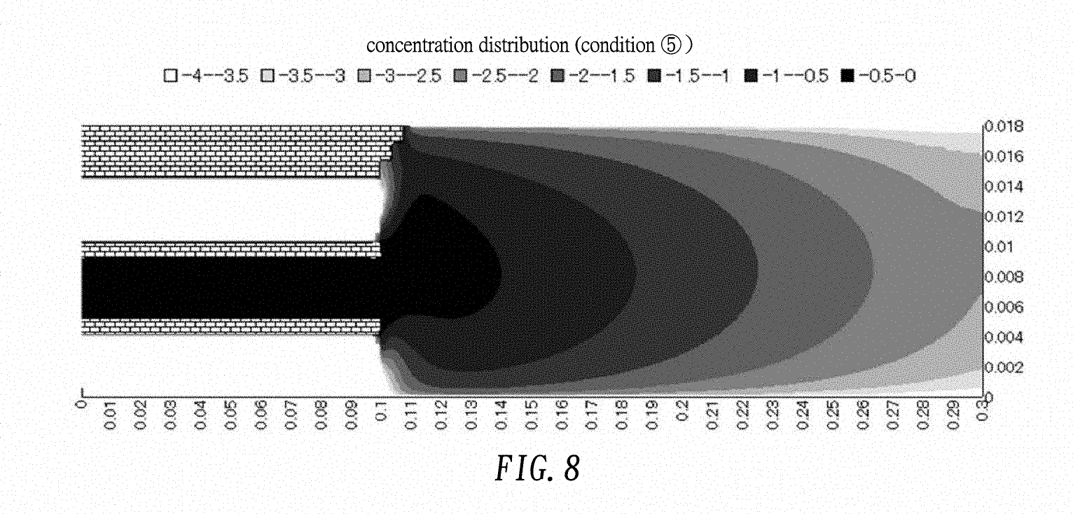

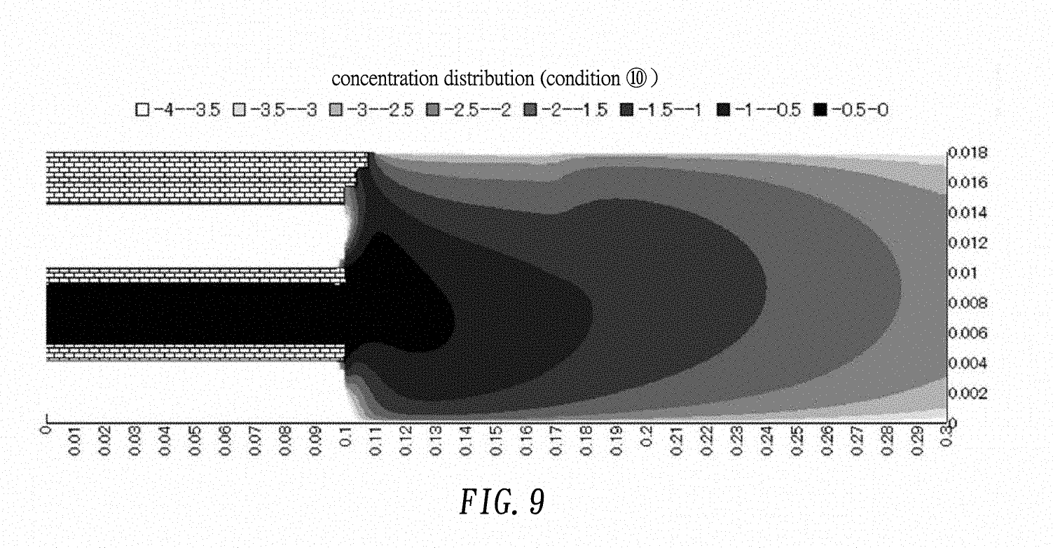

FIG. 4 shows an example of a flow pattern under “condition 1,” FIG. 5 shows an example of a flow pattern under “condition 5,” and FIG. 6 shows an example of a flow pattern under “condition 10.” In addition, an example of the concentration distribution under “Condition 1” is shown in FIG. 7 by using logarithms. Similarly, an example of the concentration distribution under the “condition 5” is shown in FIG. 8, and an example of the concentration distribution under the “condition 10” is shown in FIG. 9. Although the drawings are omitted, flow pattern examples and concentration distribution examples can be similarly obtained under other conditions “conditions 2, 3, 4, 6, 7, 8, 9, 11, and 12.”

(6) Purge Amount Changed Uniformly from the Whole

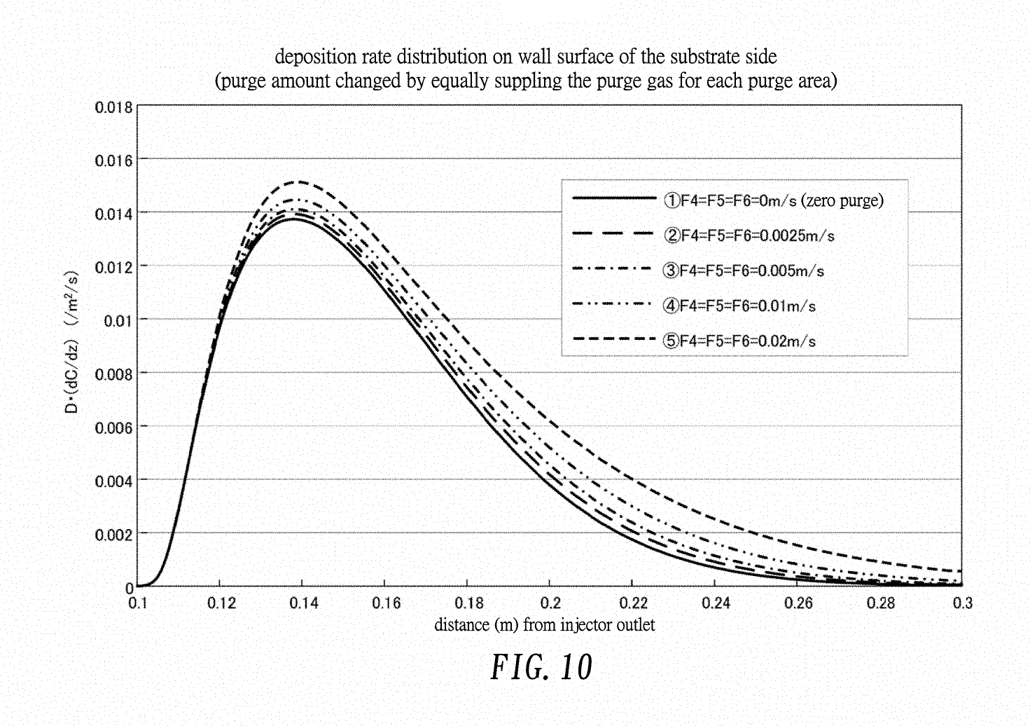

FIG. 10 shows the deposition rate distribution on wall surface 62 of the substrate side (surface of substrate or susceptor, see FIG. 3A) when the purge amount is changed uniformly from the whole (equally supplying the purge gas for F4-F6). The horizontal axis shows the distance (m) from the injector outlet and the vertical axis shows the deposition rate (D·(dC/dz) (/m²/s)). From this figure, it is confirmed that the higher the purge amount, the higher the deposition rate, (i.e., the higher the material efficiency).

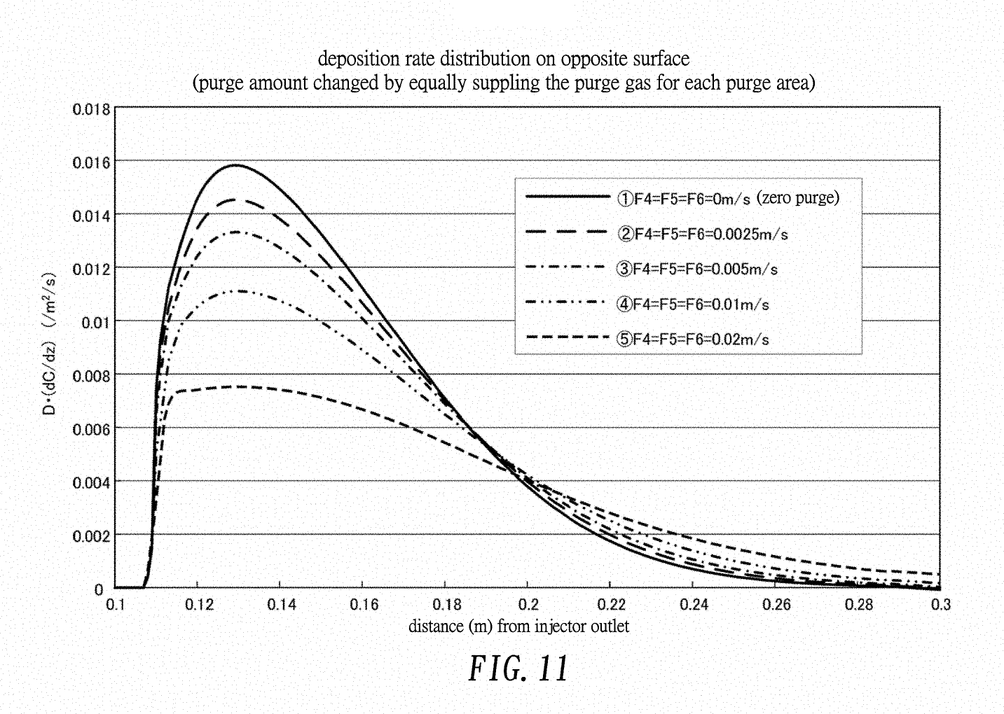

FIG. 11 shows the deposition rate distribution on the opposite surface when the purge amount is changed uniformly from the whole. The horizontal axis shows the distance (m) from the injector outlet and the vertical axis shows the deposition rate (D·(dC/dz) (/m²/s)). From this figure, it is confirmed that the deposition on the opposite surface 64 (see FIGS. 3A and 3B) decreases as the purge amount increases.

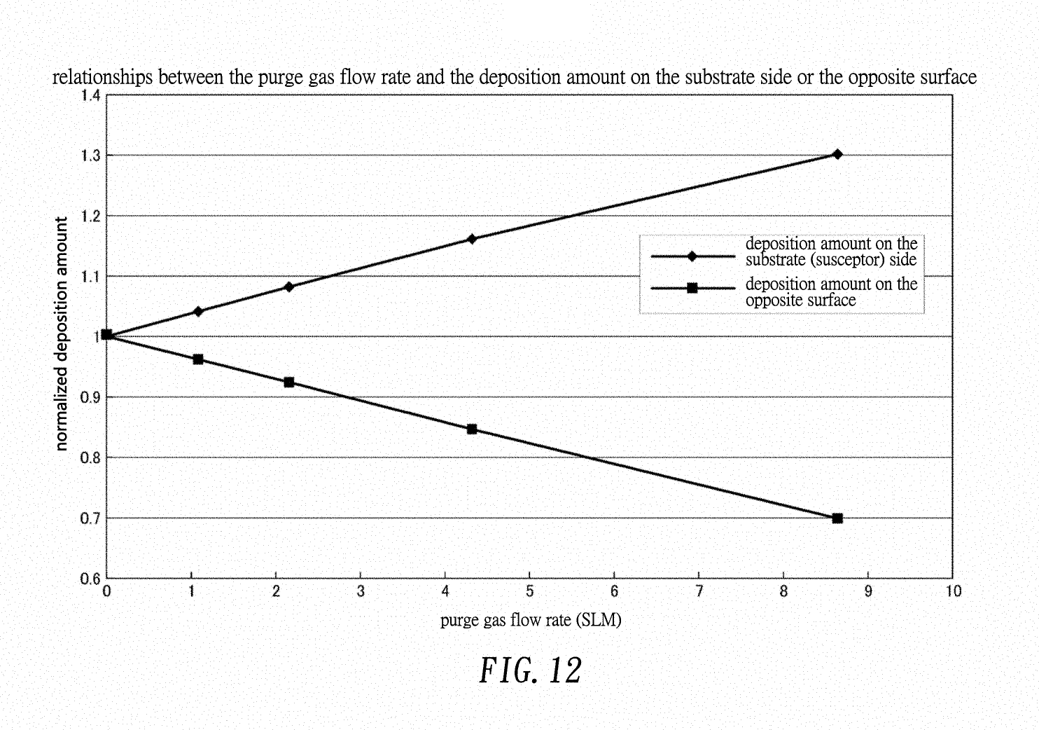

FIG. 12 shows the change in the deposition amount on wall surface 62 of the substrate side and the opposite surface 64 with respect to the purge gas flow rate. In this figure, the horizontal axis represents the purge gas flow rate (SLM) and the vertical axis represents the normalized deposition amount on the susceptor. Here, the normalized deposition amount on the vertical axis is calculated as follows. First, the deposition rate in FIG. 10 and so forth is a function of x, and let this function be R(x). The sum over all the x in the calculation range can be represented by a mathematical integral ∫R(x)dx.

For comparison, the integral value at zero purge flow rate is set to 1, and other conditions are normalized (relativized) accordingly. FIG. 12 is a graph plotted on both the substrate (susceptor) side and the opposite surface side. Since the deposition rate is the deposition amount per hour and is normalized, the vertical axis is expressed as “normalized deposition amount.” From FIG. 12, it is possible to compare the deposits amount on the opposite surface side or the susceptor/substrate side with respect to the opposite surface purge amount.

That is, as the purge flow rate is increased, the average deposition rate on the susceptor/substrate side is increasing. This means that the material efficiency is improved. The average deposition rate on the opposite surface is decreasing. That is, deposition on the opposite surface is preferably reduced.

(7) Purge Introduction Location Dependency

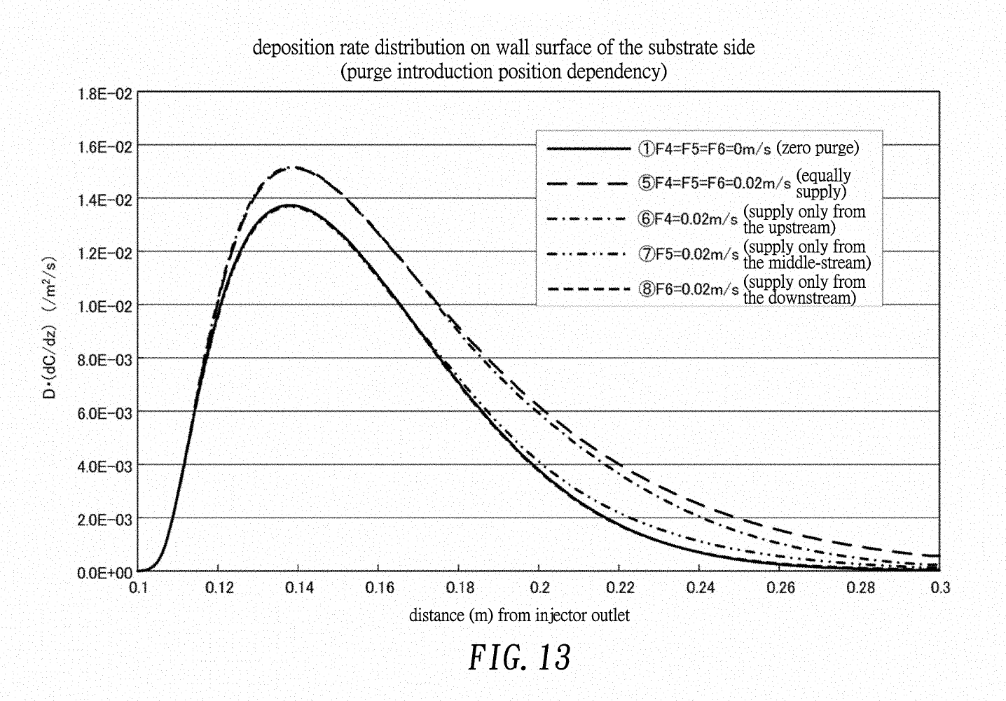

FIG. 13 shows the deposition rate distribution on the wall surface 62 of the substrate side when the purge introduction location is changed. In this figure, the horizontal axis shows the distance (m) from the injector outlet and the vertical axis shows the deposition rate (D·(dC/dz) (/m²/s)). From this figure, the introduction point of the purge gas from the upstream is most effective. And it is confirmed that the purge gas introduced from the downstream has little meaning.

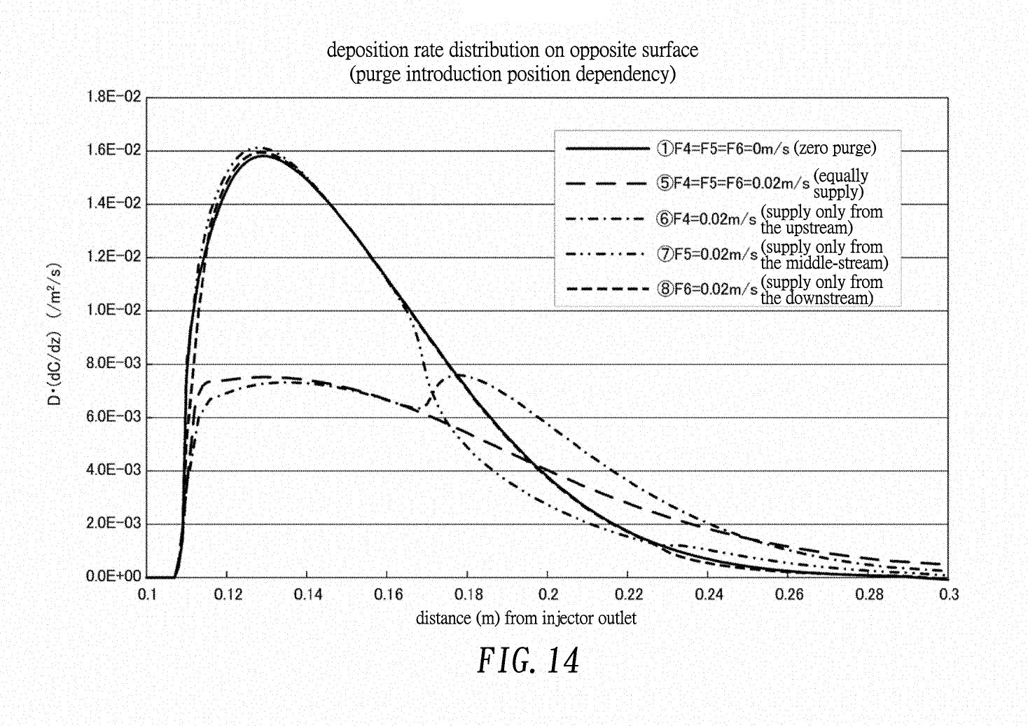

FIG. 14 shows the deposition rate distribution on the opposite surface 64 when the purge introduction location is changed. In this figure, the horizontal axis denotes the distance (m) from the injector outlet and the vertical axis denotes the deposition rate (D·(dC/dz) (/m²/s)). From this figure, it is confirmed that when purging with the same purge amount (Condition 6-Condition 8), introduction of purge gas from the upstream side has the least deposits accumulated on the opposite surface 64. Also, to compare “condition6” with “condition5”, the difference between them is small even though the purge consumption of the former is only ⅓ of the latter.

(8) In the Case that the Purge Amount is Changed by Supplying the Purge Gas Only from the Upstream Region

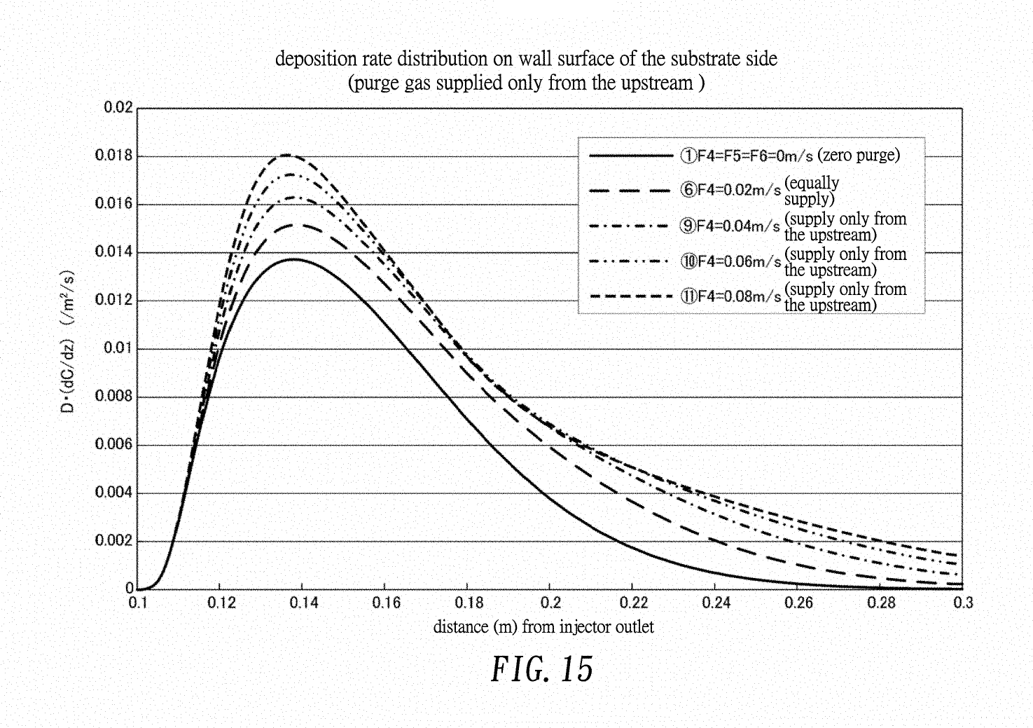

FIG. 15 shows the deposition rate distribution on the wall surface 62 of the substrate side when the purge gas is supplied only from the upstream region to change the purge amount. In this figure, the horizontal axis shows the distance (m) from the injector outlet and the vertical axis shows the deposition rate (D·(dC/dz) (/m²/s)). It is confirmed from this figure that as the purge amount increases, the deposition amount on the substrate side is larger and the material efficiency is better. Moreover, it is also confirmed that the curvature of the deposition rate curve is changed with the purge amount, so that it can be used for film-thickness uniformity control.

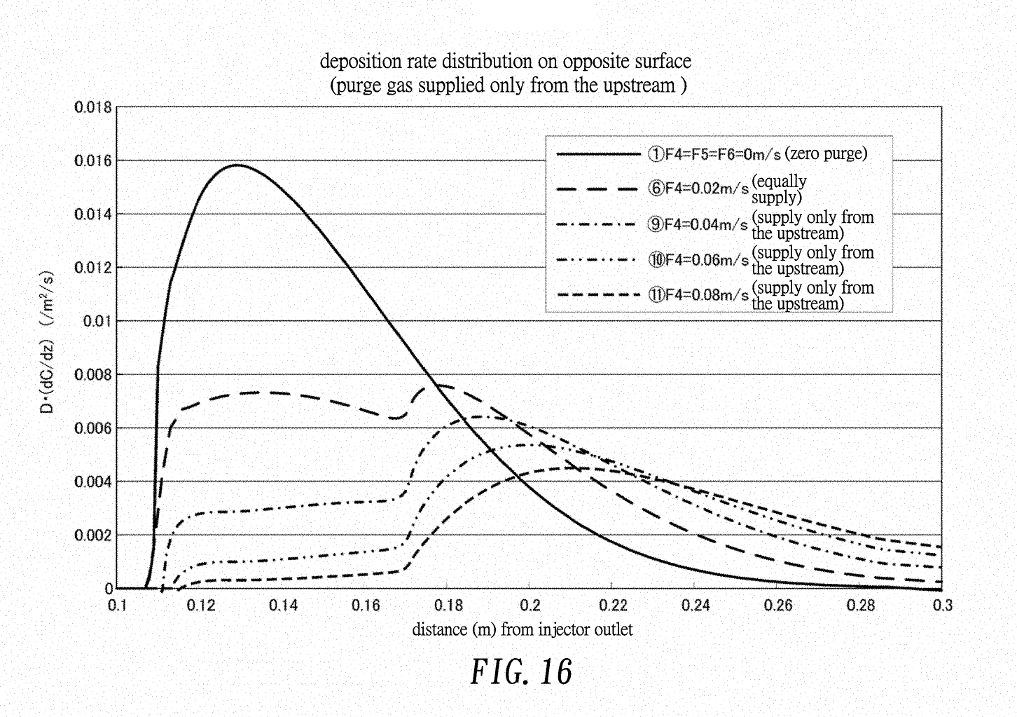

FIG. 16 shows the deposition rate distribution on the opposite surface 64 when the purge gas is supplied only from the upstream region to change the purge amount. In this figure, the horizontal axis represents the distance (m) from the injector outlet and the vertical axis represents the deposition rate (D·(dC/dz) (/m²/s)). From this figure, it is confirmed that the deposition on the opposite surface is decreased as the purge amount is increased.

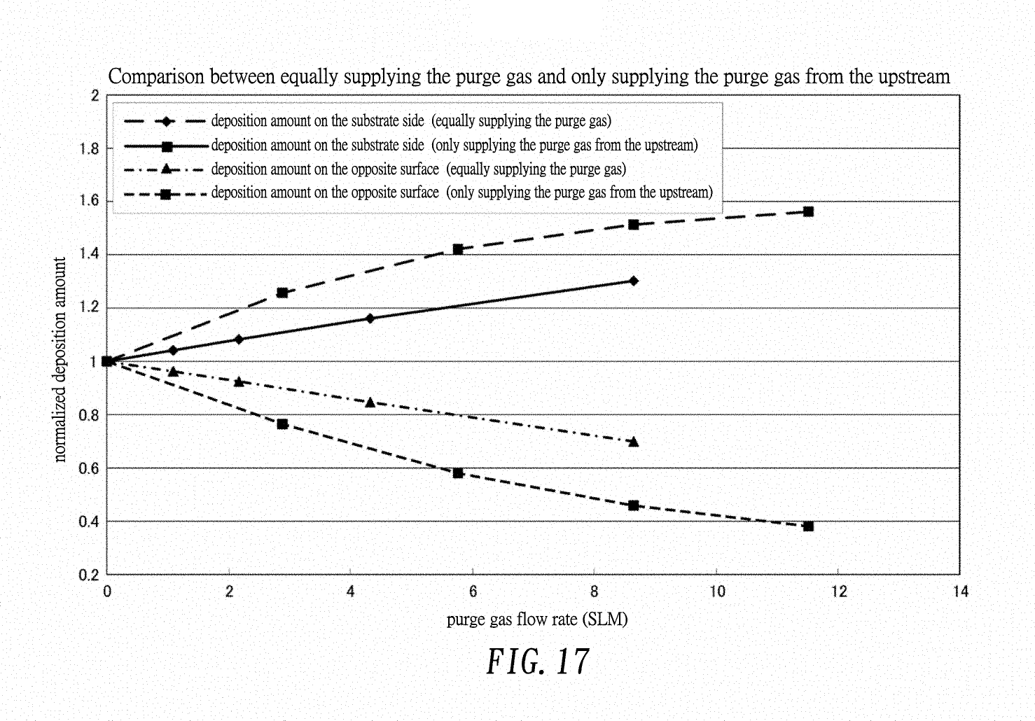

FIG. 17 shows a graph showing a comparison between the purge gas flowing from the whole and purge gas flowing only from the upstream region. The horizontal axis is the purge gas flow rate (SLM), and the vertical axis is the normalized deposition amount on the susceptor. From this figure, it was confirmed that for the same purge amount, introducing the purge gas only from the upstream region is more effective than to that from the whole.

(9) When the Purge Rate is Fixed and the Purge Ratios are Changed at the Introduction Locations.

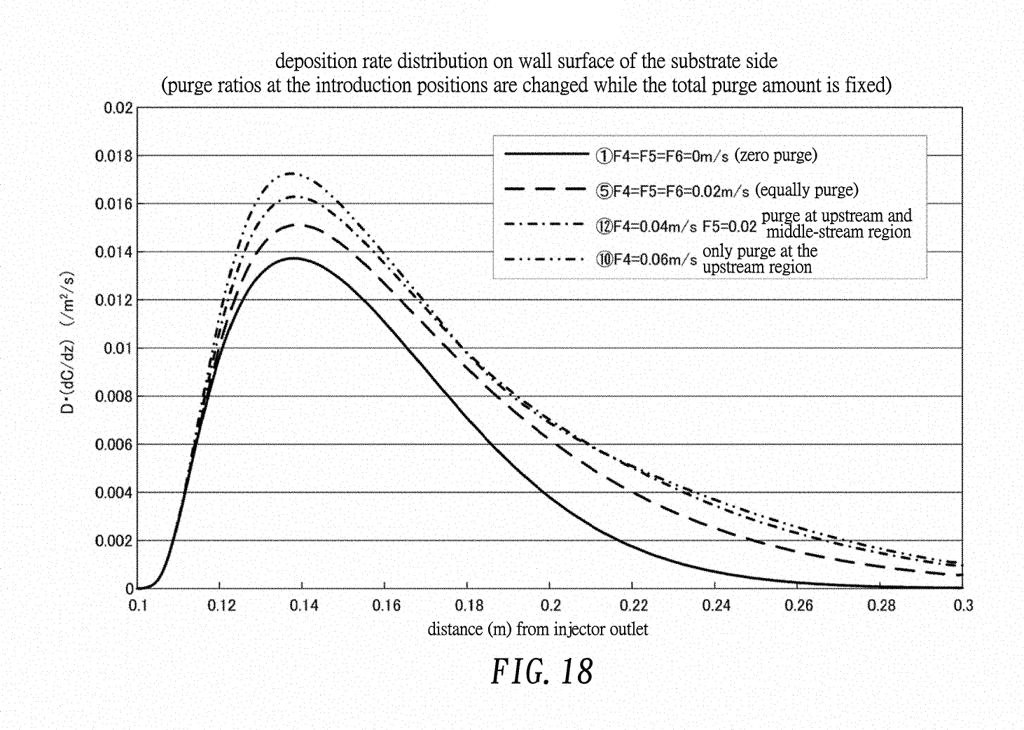

FIG. 18 shows the deposition rate distribution on the wall surface 62 of substrate side, wherein the purge ratios are changed at different introduction locations and the total purge amount is fixed. In addition, the horizontal axis shows the distance (m) from the injector outlet and the vertical axis shows the deposition rate (D·(dC/dz) (/m²/s)). From this figure, it is confirmed that “material 10” has a slightly higher material efficiency (but not a large difference) in “condition 10” and “condition 12.” Moreover, since the pattern (curvature) of the deposition rate distribution is changed, it can be used for optimization of film thickness distribution.

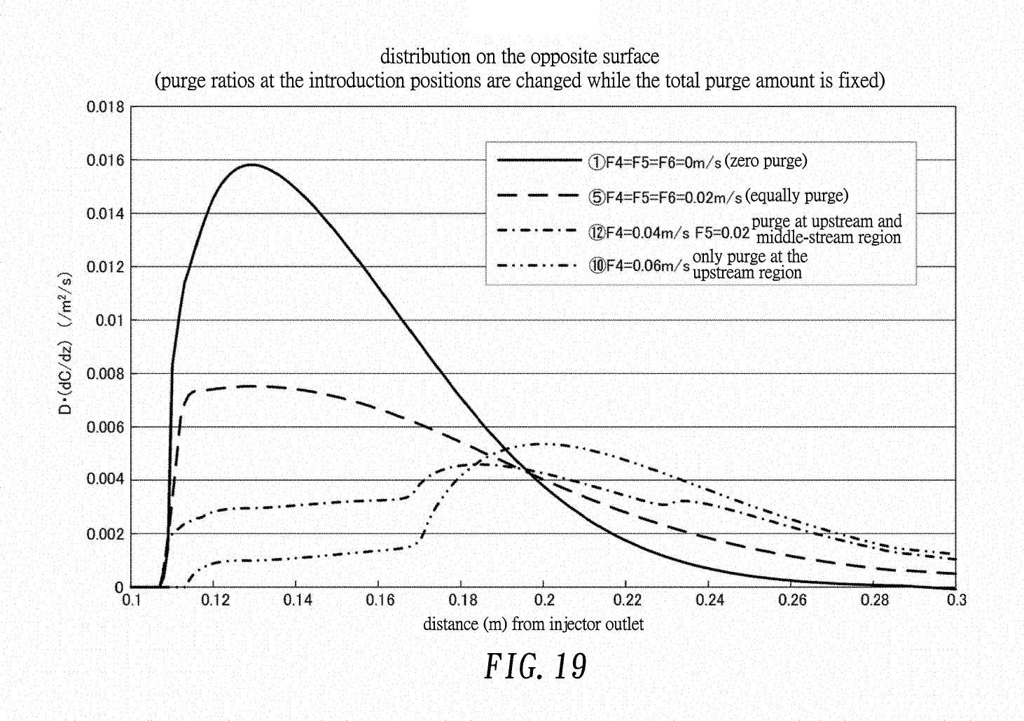

FIG. 19 shows the deposition rate distribution on the opposite surface 64 when the purge ratios are changed for different introduction locations while the total purge amount is fixed. In this figure, the horizontal axis represents the distance (m) from the injector outlet and the vertical axis represents the deposition rate (D·(dC/dz) (/m²/s)). From this figure, it is confirmed that the maximum deposition rate was the best and smallest with “condition 12” (the difference between it and “condition 10” is not large).

(10) Summary

A summary of the above simulation results is listed in the following Table 3. For ease to understand, the purge flow rate and the total purge flow rate in Table 3 are normalized by “condition 2.”

TABLE 3

| | | | | | | Deposition on | Max. deposition |
|---|---|---|---|---|---|---|---|
| | Purge flow rate | | | Total Purge | Deposition on | opposite | rate on opposite |
| Conditions | F4 | F5 | F6 | Amount | susceptor | surface | surface |
| \textcircled{1} | 0 | 0 | 0 | 0 | 1 | 1 | 1 |
| \textcircled{2} | 1 | 1 | 1 | 3 | 1.04 | 0.96 | 0.92 |
| \textcircled{3} | 2 | 2 | 2 | 6 | 1.08 | 0.92 | 0.84 |
| \textcircled{4} | 4 | 4 | 4 | 12 | 1.16 | 0.85 | 0.70 |
| \textcircled{5} | 8 | 8 | 8 | 24 | 1.30 | 0.70 | 0.48 |
| \textcircled{6} | 8 | 0 | 0 | 8 | 1.26 | 0.76 | 0.48 |
| \textcircled{7} | 0 | 8 | 0 | 8 | 1.04 | 0.96 | 1.02 |
| \textcircled{8} | 0 | 0 | 8 | 8 | 1.00 | 0.99 | 1.01 |
| \textcircled{9} | 16 | 0 | 0 | 16 | 1.42 | 0.59 | 0.41 |
| \textcircled{10} | 24 | 0 | 0 | 24 | 1.51 | 0.48 | 0.34 |
| \textcircled{11} | 32 | 0 | 0 | 32 | 1.56 | 0.40 | 0.28 |
| \textcircled{12} | 16 | 8 | 0 | 24 | 1.46 | 0.53 | 0.29 |

From Table 3, conditions 9-12 are appropriate by comprehensively considering the consumption of purge gas and the purge effect. It should be noted that which condition to be adopted may be determined by considering other factors (film thickness uniformity, etc.).

The flowing results are confirmed by the simulation:

(1) It is effective to supply purge gas from the upstream region and this is in accord with the simulation results. The reason why it is most effective to purge the upstream region is because the deposition of the upstream region is most remarkable when there is no purge under the adopted conditions.

The deposition on the opposite surface depends on various conditions, such as the material gas to be used, the flow rate of the carrier gas, the film-formation temperature, the opposite surface temperature, the film-formation pressure, and the like. For example, if the maximum deposition on the opposite surface appears to be in the midstream region, it is effective to increase the purge flow rate in the midstream region. Therefore, it is necessary to divide the opposite surface into a plurality of purge areas and the purge amount for each purge area can be adjusted in an arbitrary manner.

Generally, different types of film are formed in one batch process. As the film type changes, the state of deposition on the opposite surface also changes, so that the flow rate in each purge area in one batch must able to be changed. Therefore, it is indispensable to control the purge amount by the mass flow controller instead of the hole density or the like.

(2) According to the present invention, it is possible to optimize the purge balance. As a result, deposition on the opposite surface is suppressed, and the material efficiency of deposition on the substrate can be improved. Maintenance (cleaning) of the opposite surface should be made when deposits on the opposite surface begin to peel off. Generally, peeling occurs first in the thickest deposit. By optimizing the purge balance, it is possible not only to reduce the total amount of deposits on the opposing surface, but also to lower the maximum deposit thickness, thereby lowering the frequency of maintenance of the opposite surface and hence reducing the cost.

(3) As a secondary effect, it is possible to control the deposition rate distribution on the substrate to an extent by balancing the opposite surface purge. This effect can be applied to adjust the film thickness uniformity on the substrate.

(4) The purge gas is hydrogen (H₂) or nitrogen (N₂), or a mixed gas thereof. Nitrogen is advantageous in terms of purging effect and cost. However, some processes require a hydrogen environment, and these processes need to be purged with hydrogen. Nitrogen has a better purging effect because it has a small diffusion coefficient due to heavy molecules, so that the material molecules are difficult to be diffused to the opposite surface.

As described above, according to the first embodiment, the opposite surface 20 having a plurality of purge gas nozzles 36 for supplying the purge gas is divided into a plurality of purge areas PE1-PE3, and the flow rate of the purge gas flowing to each purge area PE1-PE3 is adjustable by MFC (Mass Flow Controller). Therefore, by optimizing the flow rate balance of the purge gas, the deposits on the opposite surface 20 can be reduced with a small purge gas amount, the maintenance frequency of the opposite surface 20 can be reduced, and the material efficiency can be improved.

### Second Embodiment

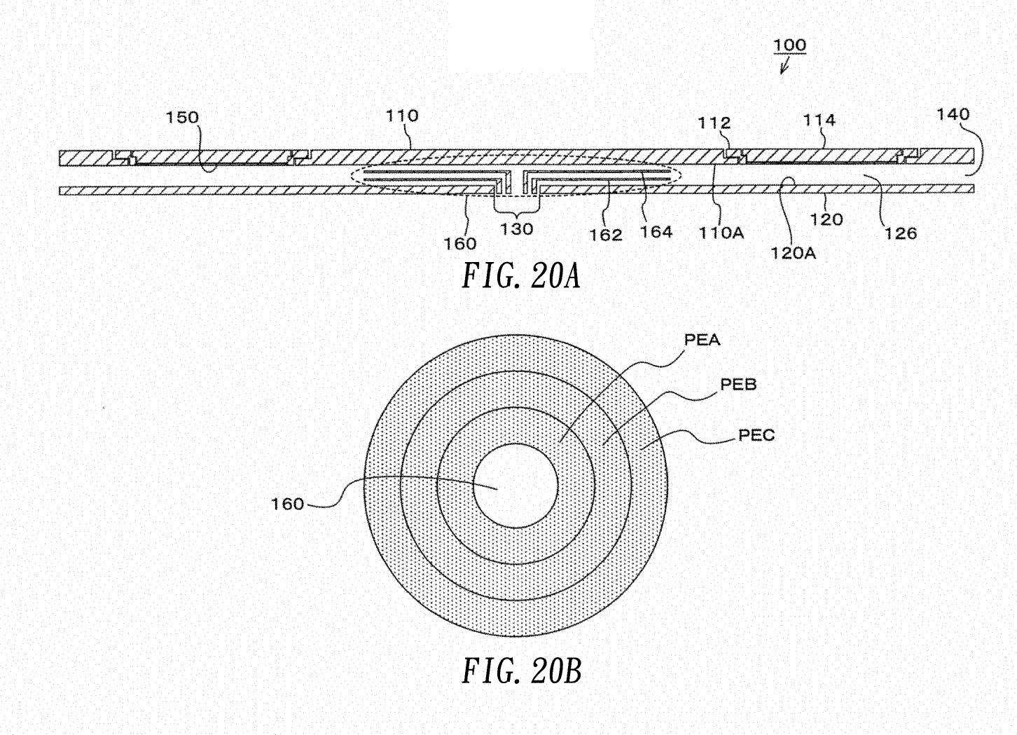

Next, a second embodiment of the present invention will be described with reference to FIG. 20. Note that the same reference numerals are used for the same or corresponding components as those of the above-described first embodiment (the same note also applies to following other embodiments). The above-mentioned first embodiment is an example of a horizontal type reaction furnace, while this embodiment is an example applied to a planetary motion type reaction furnace. FIG. 20A is a cross-sectional view showing the entire configuration of the planetary motion vapor phase film-forming apparatus of this embodiment, and FIG. 20B is a plan view of a major part showing a purge area division (or purge zone division) of the vapor phase film-forming apparatus.

As shown in FIG. 20A, the vapor phase film-forming apparatus 100 of this embodiment includes a disk-shaped susceptor 110, an opposite surface 120 facing the susceptor 110, a material gas introducing section 130, a gas exhaust section 140. A flow channel 126 is formed in the horizontal direction between the main surface 110A of the susceptor 110 and the main surface 120A of the opposite surface 120. The substrate 150 for depositing film thereon is held by a substrate holding member 114, and the substrate holding member 114 is held by a receiving portion 112 of the susceptor 110. The vapor phase film-forming apparatus 100 is centrally symmetrized. The susceptor 110 revolves about its central axis, and at the same time, the substrate 150 rotates on its axis. The mechanisms for these revolution and rotation are well-known. Further, referring to FIG. 20A, a separately supply type of injector unit 160 is also provided. The injector unit 160 is divided into three layers of upper, middle, and lower gas introduction portions by a first injector member 162 and a second injector member 164.

In this embodiment, as shown in FIGS. 20A and 20B, three concentric purge areas PEA, PEB, PEC are formed outside the peripheral of the injector unit 160. Similar to the first embodiment, a plurality of purge gas nozzles (not shown) are provided in each of the purge areas PEA-PEC, and a mass flow controller (MFC) is provided in each purge area. The mass flow rate of the purge gas is adjusted by the mass flow controller and then introduced into the flow channel 126. The other functions and effects of this embodiment are essentially the same as those of the above-described first embodiment.

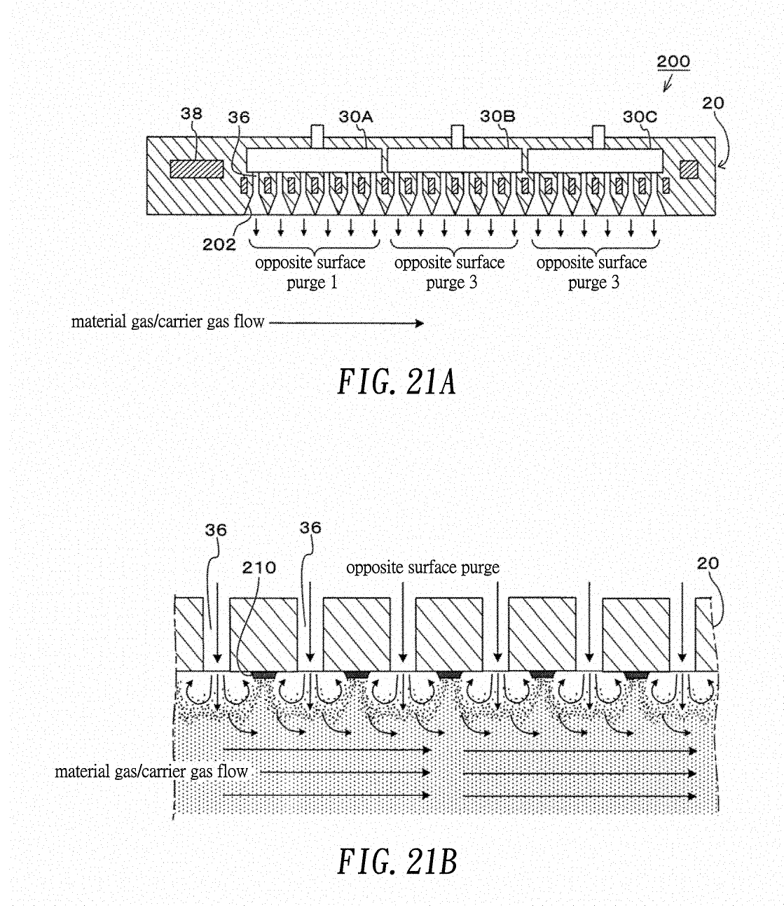

Next, a third embodiment 3 of the present invention will be described with reference to FIG. 21. This embodiment is a modification of the above-described first embodiment and relates to contrivance of the gas outlet shape of the purge gas nozzle. FIG. 21A is a cross-sectional view showing a major part of a vapor phase film-forming apparatus of the third embodiment, and FIG. 21B is a view showing a comparative example. In this embodiment, as shown in FIG. 21A, the outlet of each purge gas nozzle 36 is conical and has a reversely-tapered surface 202 enlarged toward the flow channel 40.

If such a taper is not provided, as shown in FIG. 21B, vortexes occur when the purge gas is introduced into the flow channel 40 from the purge gas nozzle 36, as indicated by arrows. The gas reaches the main surface 20A of the opposite surface 20 by riding on the vortex, and the deposit 210 is likely to be formed.

Therefore, the present embodiment deals with such vortexes by providing the reversely-tapered surface 202 at the exit of the purge gas nozzle 36 as the example shown in FIG. 21A. Accordingly, a uniform down flow is realized and the purge gas can prevent generating the vortices when the outlet shape of the nozzle 36 turns into flat, so that the material gas does not reach the opposite surface 20 and it is possible to make deposits difficult to occur. Other functions and effects of the third embodiment are the same as those in the first embodiment.

It should be noted that the present invention is not limited to the above-described embodiments, and various modifications can be made within a scope not departing from the purpose of the present invention. For example, the following features can also be included.

(1) The shapes and dimensions shown in the above embodiments are merely examples, and may be appropriately changed if necessary.

(2) The purge area (or purge zone) division shown in the above embodiment is also an example. In the above embodiment, the zones are divided into three zones in the upstream and downstream directions. However, the number of the purge zones is not limited. Also, it is not always necessary to divide it in the upstream/downstream direction, but it can be appropriately designed and changed within the range that achieves the same effect depending on the shape of the reaction furnace, the arrangement of the introduction port, and other factors.

(3) In the first embodiment, the horizontal type reaction furnace has been described as an example, but the present invention is also applicable to a planetary motion type reaction furnace as shown in the second embodiment. That is, it generally can be applied to a reactor in which a horizontal flow channel is formed. Further, the film-formation surface of the substrate may be either face-up or face-down. In the case of face-up, a purge gas nozzle capable of forming a uniform down flow is formed on the opposite surface. In the case of face-down, a purge gas nozzle capable of forming a uniform up flow is formed on the opposite surface. Even if the elements are inverted, it is not affected much by gravity.

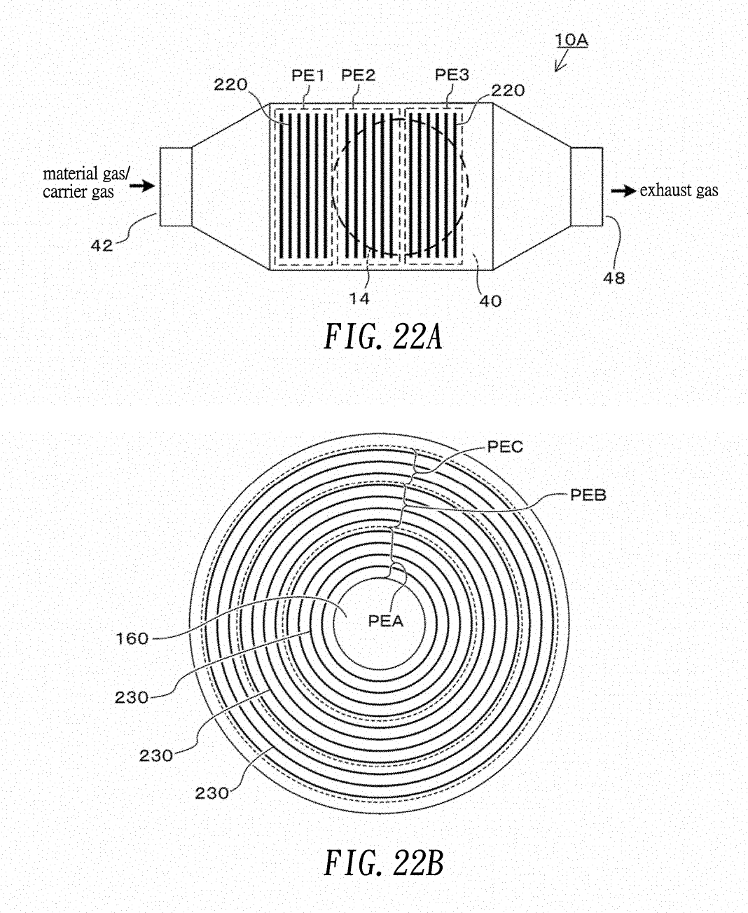

(4) In the above first embodiment, a showerhead type purge gas nozzle is used, and it may be replaced by a slit array. For example, FIG. 22A shows an arrangement example of slit nozzles where the vapor phase film-forming apparatus 10A is a horizontal type furnace, and the slit nozzle array 220 is indicated by a bold solid line in the drawing. The nozzle is slit-shaped. FIG. 22B is a view showing a slit nozzle array in a planetary motion reaction furnace. The slit nozzle array 230 is formed with concentric circles as shown by thick solid lines in the drawing.

(5) In the above first embodiment, hydrogen or nitrogen or a mixed gas thereof is used as the purge gas, but this is also an example, and various known gases can be used as the purge gas as long as it can achieve the same effect. For example, if argon or nitrides are used as material gas, then ammonia could also be used as a purge gas. In particular, when ammonia is used, it can be applied to control of the V/III ratio distribution in the flow channel

(6) Depending on the type of the material gas or the like, whether the purge amount on the upstream region or the downstream region is increased can be determined by allowing a larger amount of purge gas to flow in the portion where accumulation on the opposite surface is severe.

According to the present invention, there is provided a film-forming apparatus comprising: a susceptor for holding a film-forming substrate; an opposite surface facing the susceptor and the film-forming substrate and forming a flow channel in the horizontal direction; and introducing a material gas into the flow channel. An exhaust unit for exhausting gas passing through the flow channel; and a plurality of purge gas nozzles provided on the opposite surface and supplying purge gas uniformly toward the susceptor, wherein the plurality of purge areas are divided into a plurality of purge areas with each including a plurality of purge gas nozzles, and a plurality of mass flow controllers for controlling a purge gas flow rate are provided for each of the plurality of purge areas. Therefore, it is possible to suppress (reduce) deposits on the opposite surface, thereby improving the raw material efficiency and reducing the maintenance frequency of the opposite surface, so that it can be applied for vapor phase film-formations. In particular, it is suitable for a film-formation application of a compound semiconductor film or an oxide film.

Although specific embodiments have been illustrated and described, it will be appreciated by those skilled in the art that various modifications may be made without departing from the scope of the present invention, which is intended to be limited solely by the appended claims.

What is claimed is:

1. A film-forming apparatus comprising
a susceptor for holding a film-forming substrate;
an opposite surface facing the susceptor and the film-forming substrate and forming a flow channel in the horizontal direction;
an introduce portion for introducing a material gas into the flow channel;
an exhaust unit for exhausting the gas having passed through the flow channel; and
a plurality of purge gas nozzles provided in the opposite surface for uniformly supplying a purge gas toward the susceptor;
wherein the opposite surface is divided into a plurality of purge areas with each including a plurality of purge gas nozzles, and a plurality of mass flow controllers for controlling the flow rate of purge gas are provided for each of the plurality of purge areas.

2. The vapor phase film-forming apparatus according to claim 1, wherein the mass flow controllers perform flow rate adjustment so as to flow a large amount of purge gas to a portion where deposition on the opposite surface is severe.

3. The vapor phase film-forming apparatus according to claim 1, wherein the opposite surface is divided into a plurality of purge areas in the upstream/downstream direction when the introduction side of the material gas is set as an upstream side and the exhaust side is set as a downstream side.

4. The vapor phase film-forming apparatus according to claim 3, wherein the mass flow controllers perform flow rate adjustment so as to flow a large amount of purge gas to one of the plurality of purge areas where deposition on the opposite surface is severe.

5. The vapor phase film-forming apparatus according to claim 4, wherein the plurality of purge areas are concentric.

6. The vapor phase film-forming apparatus according to claim 1, wherein the purge gas nozzle is a shower head.

7. The vapor phase film-forming apparatus according to claim 6, wherein an outlet shape of the purge gas nozzle is reversely-tapered.

8. The vapor phase film-forming apparatus according to claim 1, wherein the purge gas nozzle is slit nozzle array.

9. The vapor phase film-forming apparatus according to claim 8, wherein an outlet shape of the purge gas nozzle is reversely-tapered.

10. The vapor phase film-forming apparatus according to claim 1, wherein the purge gas is hydrogen or nitrogen, or a mixed gas thereof.

11. The vapor phase film-forming apparatus according to claim 1, wherein the purge gas is ammonia.

12. The vapor phase film-forming apparatus according to claim 1, further comprising a cooling device for cooling the opposite surface.

13. The vapor phase film-forming apparatus according to claim 12, wherein the cooling device comprises a plurality of cooling pipes arranged between the plurality of purge gas nozzles.
